(19) United States
(12) Patent Application Publication
(10) Pub. No.: US 2026/0068711 A1
(43) Pub. Date: Mar. 5, 2026

(54) SEMICONDUCTOR PACKAGE AND PACKAGE ON BOARD

(71) Applicant: SAMSUNG ELECTRONICS CO., LTD., Suwon-si (KR)

(72) Inventors: Jae Choon KIM, Suwon-si (KR); Jae Moo CHOI, Suwon-si (KR); Junsoo KIM, Suwon-si (KR)

(21) Appl. No.: 19/049,870

(22) Filed: Feb. 10, 2025

(30) Foreign Application Priority Data
Sep. 5, 2024 (KR) 10-2024-0120766

(51) Int. Cl. H01L 23/538; H01L 21/56; H01L 23/00; H01L 23/18; H01L 23/31; H01L 23/367; H01L 25/16; H10B 80/00; H10D 80/30

(52) U.S. Cl. CPC H01L 23/5386; H10B 80/00; H10D 80/30

(57) ABSTRACT

The present disclosure provides a semiconductor package including: a substrate; a socket on the substrate and including a socket body having a mounting region on which a first semiconductor chip is mounted and socket pins penetrating the socket body and electrically connected to the substrate; and one or more second semiconductor chips disposed side by side on the substrate adjacent the socket.

### CROSS-REFERENCE TO RELATED APPLICATION

This application claims priority to and the benefit of Korean Patent Application No. 10-2024-0120766, filed in the Korean Intellectual Property Office on Sep. 5, 2024, the entire contents of which are incorporated herein by reference.

### BACKGROUND

The present disclosure relates to a semiconductor package and a package on board.

In a semiconductor package industry, a 2.5D package structure is known in which a high bandwidth memory (HBM) chip and a logic chip are disposed side by side on an interposer substrate and mounted on a package substrate. The 2.5D package enables a high-rate data transmission and has an excellent heat dissipation characteristic, so it can be applied to high-performance computing products.

If a defect occurs in the HBM in the 2.5D package, it is difficult to replace just the HBM, so the entire product must be replaced, which may cause a yield deterioration of the product. In addition, when the generation of the HBM is changed, a time and cost are consumed for manufacturing the 2.5D package to which the changed generation of the HBM is applied. In addition, it is difficult to perform the characteristic verification of HBM at the package level and a board level before applying the HBM to the product.

### SUMMARY

The present disclosure, in one aspect, provides a semiconductor package and a package on board that enable increased ease of replacement of a semiconductor chip.

The present disclosure, in another aspect, provides a semiconductor package and a package on board that enable an electrical inspection of the semiconductor chip at the package level and the board level.

The present disclosure according to some embodiments provides a semiconductor package including: a substrate; a socket on the substrate and including a socket body having a mounting region on which a first semiconductor chip is mounted and socket pins penetrating the socket body and electrically connected to the substrate; and one or more second semiconductor chips disposed side by side on the substrate adjacent the socket.

The present disclosure according to some other embodiments provides a semiconductor package including: a first substrate; and a sub-semiconductor package on the first substrate, wherein the sub-semiconductor package includes: a second substrate; a socket on the second substrate and including a socket body having a mounting region on which a first semiconductor chip is mounted, and socket pins penetrating the socket body and electrically connected to the second substrate; and a second semiconductor chip on the second substrate adjacent the socket.

The present disclosure according to some other embodiments provides a package on board including: a first substrate; a second substrate on the first substrate; and a semiconductor package on the second substrate, wherein the semiconductor package includes: a third substrate; a first socket on the third substrate and including a first socket body having a mounting region on which a first semiconductor chip is mounted, and first socket pins penetrating the first socket body and electrically connected to the third substrate; and a second semiconductor chip on the third substrate adjacent the first socket.

According an aspect of the present disclosure, the semiconductor package and the package on board with increased ease of replacement of the semiconductor chip may be provided.

According to another aspect of the present disclosure, the semiconductor package and the package on board capable of an electrical inspection of the semiconductor chip at a package level and a board level may be provided.

### BRIEF DESCRIPTION OF THE DRAWINGS

FIG. 1 is a cross-sectional view of a semiconductor package according to some embodiments.

FIG. 2 is an enlarged view of a socket of FIG. 1.

FIG. 3 is a cross-sectional view of a semiconductor package according to some embodiments.

FIG. 4 is a cross-sectional view of a semiconductor package according to some embodiments.

FIG. 5 is a cross-sectional view of a semiconductor package according to some embodiments.

FIG. 6 is a cross-sectional view of a semiconductor package according to some embodiments.

FIG. 7 is a cross-sectional view of a 2.5D semiconductor package that includes a semiconductor package of FIG. 1 as a sub-semiconductor package.

FIG. 8 is a top view of a semiconductor package illustrated in FIG. 7.

FIG. 9 is a cross-sectional view of a 2.5D semiconductor package according to some embodiments.

FIG. 10 is a cross-sectional view of the package on board according to some embodiments.

FIG. 11 is a view illustrating an example method for performing an electrical inspection of a semiconductor chip in a package on board illustrated in FIG. 10.

FIG. 12 is a view showing a semiconductor chip accommodated in an accommodating groove of a socket in a package on board illustrated in FIG. 10 and connected to a socket.

FIG. 13 is an example cross-sectional view of a semiconductor chip connected to a socket.

FIG. 14 is a cross-sectional view of a package on board according to some embodiments.

FIG. 15 is a cross-sectional view of the package on board according to some embodiments.

FIG. 16 is a cross-sectional view of a package on board according to some embodiments.

FIG. 17 is a view illustrating an example method for performing an electrical testing on a package on board illustrated in FIG. 14.

FIG. 18 is a view showing an example method for performing an electrical testing on a package on board according to a variation.

FIG. 19 is a cross-sectional view of a package on board according to some embodiments.

FIG. 20 is a cross-sectional view of a package on board according to some embodiments.

FIG. 21 is a cross-sectional view of a package on board according to some embodiments.

FIG. 22 to FIG. 24 are views illustrating an example manufacturing method for a semiconductor package illustrated in FIG. 1.

### DETAILED DESCRIPTION

The present disclosure will be described more fully hereinafter with reference to the accompanying drawings, in which example embodiments of the disclosure are shown. As those skilled in the art would realize, the example embodiments may be modified in various different ways, all without departing from the spirit or scope of the present disclosure.

Descriptions of parts not related to the present invention may omitted in the interest of brevity, and like reference numerals designate like elements throughout the specification.

Further, since sizes and thicknesses of constituent members shown in the accompanying drawings may be arbitrarily given for better understanding and ease of description, the present disclosure is not limited to the illustrated sizes and thicknesses. In the drawings, the thickness of layers, films, panels, regions, etc., may be exaggerated for clarity. In the drawings, for better understanding and ease of description, the thicknesses of some layers and areas may be exaggerated.

Throughout this specification and the claims that follow, when it is described that an element is “coupled” to another element, the element may be “directly coupled” to the other element or “indirectly coupled” to the other element through a third element. From a similar perspective, this includes not only being “physically connected” but also being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Additionally, throughout the specification, the sequential numbers, such as a first, a second, etc., are used to distinguish a component from other identical or similar components, and are not necessarily intended to refer to a specific component. Thus, a component referred to as a first component in a particular part of this specification may be referred to as a second component in another part of this specification.

Additionally, throughout the specification, a singular reference to any component includes a plurality of references to that component, unless otherwise stated.

Additionally, throughout the specification, references to directions such as an upper surface, an upper side, an upper part, a lower surface, a lower side, a lower part, etc. may be provided with reference to the drawings to aid explanation and understanding.

Hereinafter, a semiconductor package and a package on board according to example embodiments of the present disclosure are described with reference to accompanying drawings.

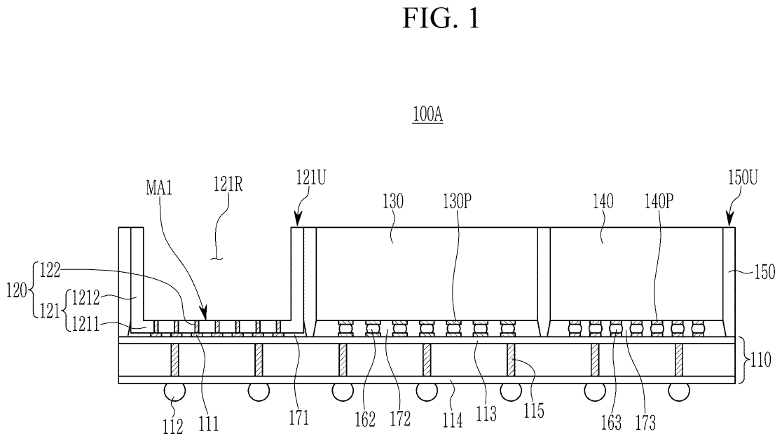

FIG. 1 is a cross-sectional view of a semiconductor package according to some embodiments.

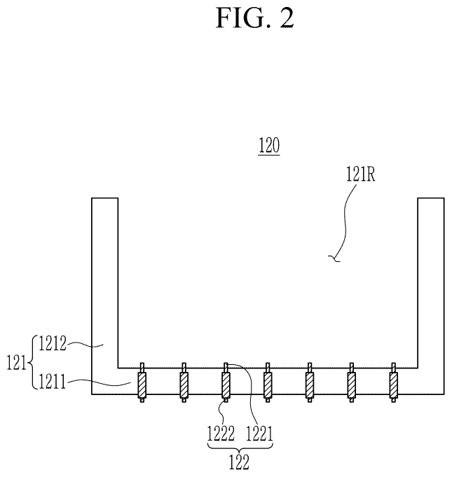

FIG. 2 is an enlarged view of a socket of FIG. 1.

Referring to the drawings, a semiconductor package 100A may include a first substrate 110, a first socket 120, one or more semiconductor chips 130 and 140 disposed side by side on the first substrate 110, an encapsulant 150 encapsulating or surrounding the first socket 120.

The first substrate 110 may be an interposer substrate. The interposer substrate may be, for example, a silicon interposer substrate, an organic interposer substrate, or a glass interposer substrate.

The first substrate 110 may include pads 111 disposed on the upper surface and conductive bumps 112 disposed on the lower surface.

Each of the pads 111 may be connected to the first socket 120 or one of the semiconductor chips 130 and 140. A conductive material may be used as the material of the pad 111, for example copper (Cu), aluminum (Al), gold (Au), platinum (Pt), silver (Ag), tin (Sn), chromium (Cr), palladium (Pd), or an alloy of two or more of these.

The conductive bumps 112 may connect the first substrate 110 to other components, such as a second substrate 210 described below. There are no special restrictions on the number, spacing, or arrangement of conductive bumps 112.

Additionally, the first substrate 110 may further include upper wire layer(s) 113, lower wire layer(s) 114, and through vias 115 connecting the upper wire layer 113 and the lower wire layer 114.

The first socket 120 may include a first socket body 121 and first socket pins 122.

The material of the first socket body 121 may be an insulating material, but a conductive material may also be used if necessary. When using the conductive material as the material of the first socket body 121, an electrical insulation with the first socket pins 122 may be required.

The first socket body 121 may have a mounting region MA1 on which the first semiconductor chip 190, described below, is mounted. The first semiconductor chip 190 may be connected to or separated from the first socket 120 by a simple mounting and a dismounting.

In some embodiments, the first socket body 121 may include a bottom surface or bottom wall 1211 providing the mounting region MA1 and a sidewall or side surface 1212 extending from the edge of the bottom surface 1211 and upward from the bottom surface 1211. The mounting region MA1 may be a part or all of the bottom surface 1211 of the first socket body 121 where the first semiconductor chip 190 is mounted. The bottom surface 1211 and the sidewall 1212 of the first socket body 121 may be connected to each other to provide the accommodating groove 121R in which the first semiconductor chip 190 is accommodated. The first semiconductor chip 190 may be inserted into the accommodating groove 121R and be disposed on the bottom surface 1211, so that it may be easily mounted on the mounting region MA1.

The first socket pins 122 may pass through the first socket body 121 in the mounting region MA1 and may be electrically connected to the first substrate 110.

Referring to FIG. 2, the upper end 1221 and the lower end 1222 of the first socket pin 122 may be exposed on the first socket body 121 for the connection with the first semiconductor chip 190 and the first substrate 110, respectively. For example, the upper end 1221 and the lower end 1222 of the first socket pin 122 may protrude from the first socket body 121. The upper end 1221 of the first socket pin 122 may have a shape suitable for mounting the conductive bump 195 of the first semiconductor chip 190 (e.g., a shape in which the center region is more concave than the edge region surrounding it).

For the first socket pin 122, a pogo pin, a probe head, or a silicon rubber pin may be used, but the type of the first socket pin 122 is not limited to these.

Referring again to FIG. 1, in some embodiments, the first socket 120 may be fixed on the first substrate 110 with an underfill resin 171. The underfill resin 171 may fill at least part of the space between the first socket body 121 and the first substrate 110, enabling the first socket body 121 and the first substrate 110 to be connected.

However, the underfill resin 171 may be omitted, and the first socket 120 may be fixed on the first substrate 110 with the encapsulant 150.

The second semiconductor chip 130 may be disposed on the first substrate 110 and may be electrically connected to the first substrate 110. The second semiconductor chip 130 may be disposed between the first socket 120 and the third semiconductor chip 140 on the first substrate 110, for example. The second semiconductor chip 130 may have a connection pad 130P, and the connection pad 130P may be disposed to face the pad 111 of the first substrate 110 and may be electrically connected thereto.

The conductive bump 162 may be disposed between the connection pad 130P of the second semiconductor chip 130 and the pad 111 of the first substrate 110 to connect them. A conductive material such as a solder may be used as the material for conductive bump 162. The conductive bump 162 may be covered with or surrounded by the underfill resin 172 that fills the space between the second semiconductor chip 130 and the first substrate 110, but the underfill resin 172 may be omitted.

The second semiconductor chip 130 may include a logic chip. For example, the second semiconductor chip 130 may include one or more of an application processor (AP), a microprocessor, a central processing unit (CPU), a graphic processing unit (GPU), a neural processing unit (NPU), an application specific integrated circuit (ASIC), and a system on chip (SoC).

The third semiconductor chip 140 may be disposed on the first substrate 110 and may be electrically connected to the first substrate 110. The third semiconductor chip 140 may have a connection pad 140P, and the connection pad 140P may be disposed to face the pad 111 of the first substrate 110 and may be electrically connected thereto.

A conductive bump 163 may be disposed between the connection pad 140P of the third semiconductor chip 140 and the pad 111 of the first substrate 110 to connect them. A conductive material such as a solder may be used as the material for conductive bump 163. The conductive bump 163 may be covered or surrounded by an underfill resin 173 that may fill the space between the second semiconductor chip 130 and the first substrate 110, but the underfill resin 173 may be omitted.

The third semiconductor chip 140 may include a memory chip, for example a high bandwidth memory (HBM) chip. The memory chip may include other types of memory chips, such as dynamic random access memory (DRAM) chips, static random access memory (SRAM) chips, flash memory chips, read-only memory (ROM) chips, and magnetic random access memory (MRAM) chips.

The encapsulant 150 may encapsulate or surround side surfaces of the first socket 120, the second semiconductor chip 130, and the third semiconductor chip 140 on the first substrate 110.

An insulating material such as an epoxy molding compound (EMC) may be used as the material for the encapsulant 150.

The upper surface 121U of the first socket body 121, the upper surface of the second semiconductor chip 130, and/or the upper surface of the third semiconductor chip 140 may be exposed through the upper surface 150U of the encapsulant 150.

The upper surface 121U of the first socket body 121 and the upper surface 150U of the encapsulant 150 may be coplanar or substantially coplanar. In the present disclosure, ‘substantially coplanar’ means including cases where there are fine level differences due to errors in the process. As described below, the first socket 120 having a shape before a processing may be mounted on the first substrate 110 and encapsulated with the encapsulant 150, and then the encapsulant 150 and the first socket body 121 may be grinded to form the first socket body 121 having the accommodating groove 121R. By grinding the encapsulant 150 and the first socket body 121 together, the upper surface 121U of the first socket body 121 and the upper surface 150U of the encapsulant 150 may have a coplanar structure.

The upper surface of the second semiconductor chip 130 and/or the third semiconductor chip 140 may also be coplanar or substantially coplanar with the upper surface 150U of the encapsulant 150. This is because the upper surfaces of the second semiconductor chip 130 and the third semiconductor chip 140 may be grinded together during the grinding.

Additionally, the side surface of the encapsulant 150 may be coplanar or substantially coplanar with the side surface of the first substrate 110. When manufacturing the semiconductor package, the first socket 120 and the semiconductor chips 130 and 140 may be mounted on the first substrate 110 of a wafer level, encapsulated by the encapsulant 150, and then the encapsulant 150 and the first substrate 110 may be sawed to manufacture individual semiconductor packages. Since the encapsulant 150 and the first substrate 110 are sawed together during the sawing, the side surface of the encapsulant 150 may have a coplanar structure with the side surface of the first substrate 110.

According to the present disclosure, the first socket 120 is introduced and the semiconductor chip mounted thereon is connected to the first substrate 110. The semiconductor chip mounted on the first socket 120 may be connected to or separated from the first socket 120 by a simple mounting and detachment. Therefore, the defective semiconductor chip in the semiconductor package may be easily replaced. In addition, even if the semiconductor chip is replaced with the next generation semiconductor chip, if the bump map is designed identically to that of the conventional semiconductor chip, it may be applied interchangeably to the same semiconductor package. In addition, the semiconductor package may be used for an electrical inspection of the semiconductor chips at the package level (or the board level).

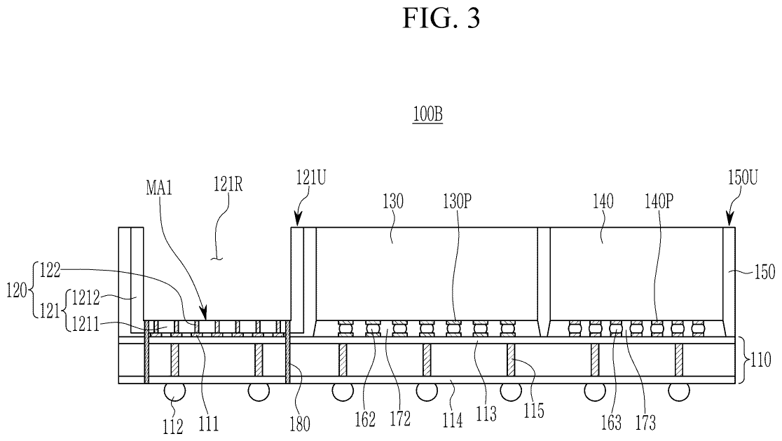

FIG. 3 is a cross-sectional view of a semiconductor package according to some embodiments.

In the semiconductor package 1001B, the first socket 120 may be fixed on the first substrate 110 by a bonding device or connection device or fastening device 180.

The bonding device 180 may penetrate the first socket body 121 and the first substrate 110 to bond or connect or fasten the first socket body 121 and the first substrate 110. For example, the bonding device 180 may penetrate the bottom surface 1211 of the first socket body 121 and the first substrate 110, and bond the first socket body 121 and the first substrate 110.

The bonding device 180 may be a screw, a bolt, a nut, etc.

For other configurations, the same provisions as those described elsewhere in this specification may be applied, unless otherwise specifically contradicted.

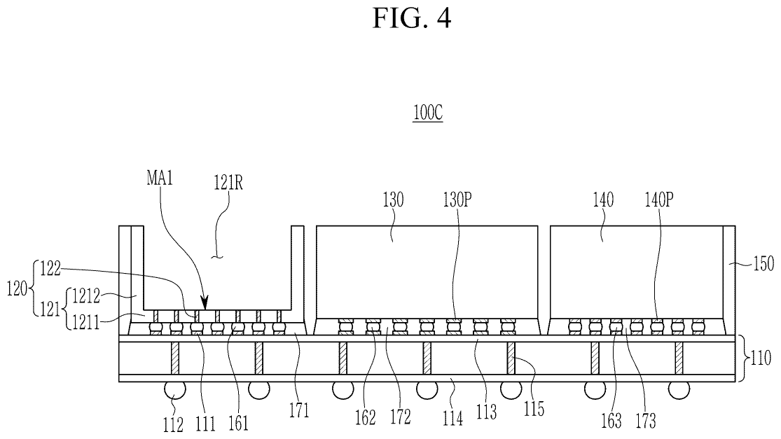

FIG. 4 is a cross-sectional view of a semiconductor package according to some embodiments.

In a semiconductor package 1000, the first socket 120 may be mounted and fixed on the first substrate 110 with a conductive bump 161. Additionally, the first socket 120 may be connected to the first substrate 110 via the conductive bump 161. The conductive bump 161 may be disposed between the lower end 1222 of the first socket pin 122 and the pad 111 of the first substrate 110 to connect them. A conductive material such as a solder may be used as the material for conductive bump 161. The conductive bump 161 may be covered or surrounded by an underfill resin 171 that may fill the space between the first socket 120 and the first substrate 110, but the underfill resin 171 may be omitted.

For other configurations, the same provisions as those described elsewhere in this specification may be applied, unless otherwise specifically contradicted.

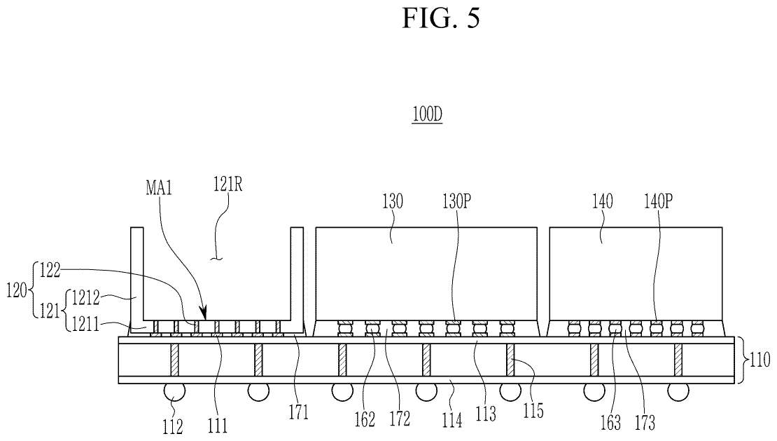

FIG. 5 is a cross-sectional view of a semiconductor package according to some embodiments.

The semiconductor package 100D may not include an encapsulant 150. If the semiconductor package 100D does not include the encapsulant 150, a machining to form the accommodating groove 121R of the first socket 120 may not be required during the manufacturing process of the semiconductor package.

For other configurations, the same provisions as those described elsewhere in this specification may be applied, unless otherwise specifically contradicted.

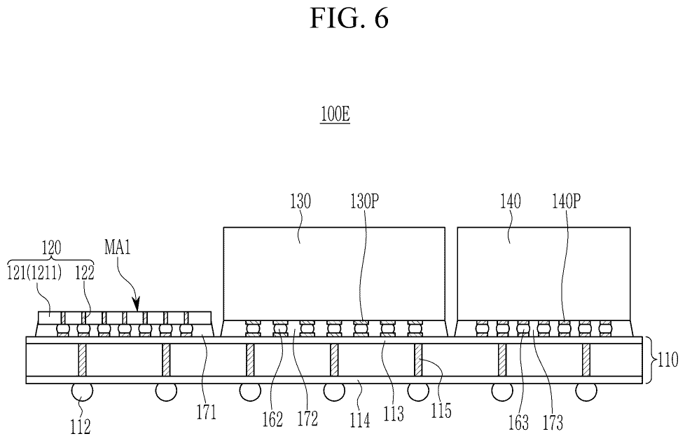

FIG. 6 is a cross-sectional view of a semiconductor package according to some embodiments.

The first socket body 121 of the semiconductor package 100E may include only the bottom surface 1211 and may not include the sidewall 1212. The first semiconductor chip 190 may be mounted on the mounting region MA1 of the first socket body 121 by a vision recognition.

Additionally, the semiconductor package 100E may not include the encapsulant 150.

For other configurations, the same provisions as those described elsewhere in this specification may be applied, unless otherwise specifically contradicted.

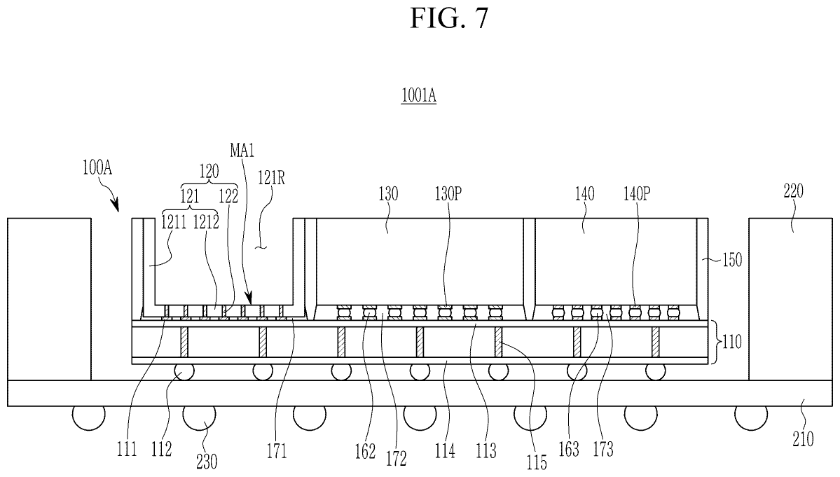

FIG. 7 is a cross-sectional view of a 2.5D semiconductor package that includes the semiconductor package of FIG. 1 as a sub-semiconductor package.

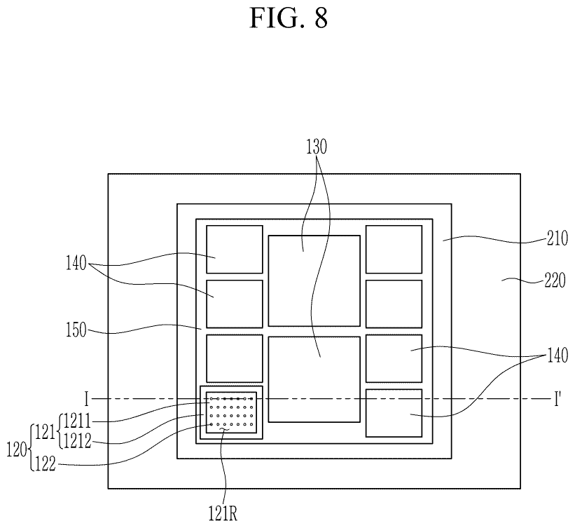

FIG. 8 is a top view of the semiconductor package illustrated in FIG. 7.

Specifically, FIG. 7 is a cross-sectional view of FIG. 8 taken along a line I-I′.

The semiconductor package 1001A according to some embodiments may include a semiconductor package 100A, which is a sub-semiconductor package, and a second substrate 210 on which the semiconductor package 100A is disposed.

The description of the semiconductor package 100A and the components of semiconductor package 100A may be applied equally to the descriptions given elsewhere in this specification, unless otherwise specifically contradicted.

Additionally, the sub-semiconductor package included in semiconductor package 1001A is not limited to the semiconductor package 100A, and may be a semiconductor package 100B, 1000, 100D, and 100E according to other embodiments.

The second substrate 210 may be a package substrate for providing a 2.5D package.

The second substrate 210 may include conductive bumps 230 disposed on the lower surface. The conductive bumps 230 may connect the second substrate 210 to other components, such as a third substrate 310 described below. A conductive material such as a solder may be used as the material for conductive bump 230. There are no special restrictions on the number, spacing, or arrangement of conductive bumps 230.

A stiffener 220 may be disposed on the second substrate 210 to be spaced apart from the semiconductor package 100A. The stiffener 220 may play a role in improving thermal characteristics, mechanical strengths, and electric characteristics of the semiconductor package 100A. In some embodiments, the stiffener 220 may be disposed on the second substrate 210 in a manner that surrounds the semiconductor package 100A. The material for the stiffener 220 may be a metal such as copper (Cu), aluminum (AI), alloys of metals, ceramics, etc. The upper surface of the stiffener 220 and the upper surface of the semiconductor package 100A may be coplanar or substantially coplanar for the stable bonding with other components disposed thereon.

Referring to FIG. 8, the semiconductor package 100A may include a plurality of second semiconductor chips 130 and a plurality of third semiconductor chips 140. For example, the semiconductor package 100A may include the second semiconductor chips 130, which are logic chips, and the third semiconductor chips 140, which are high bandwidth memory chips. According to the present disclosure, at least one (e.g., the third semiconductor chip(s) 140 of the semiconductor chips 130 and 140 is replaced in the semiconductor package 100A, and the first socket 120 is disposed, and the replaced semiconductor chip is connected to the first substrate 110 through the first socket 120. The first semiconductor chip 190 may be connected to or separated from the first socket 120 by a simple mounting and dismounting.

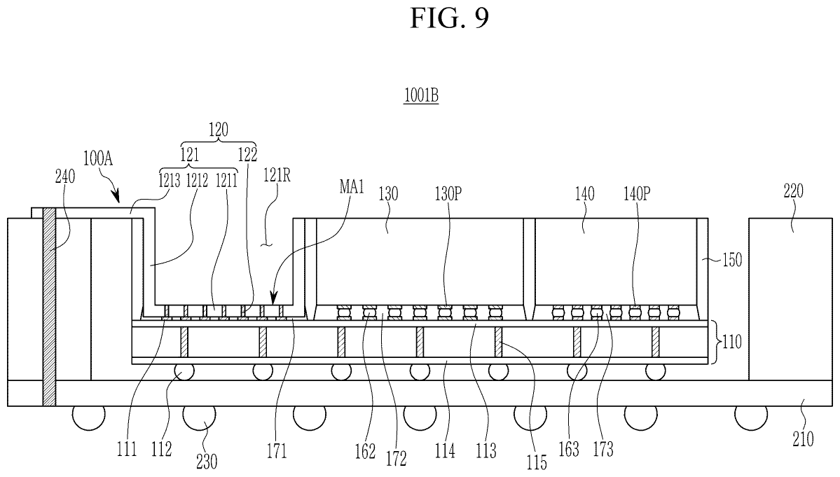

FIG. 9 is a cross-sectional view of a 2.5D semiconductor package according to some embodiments.

Compared with the semiconductor package 1001A, in the semiconductor package 1001B, the first socket body 121 may extend onto the stiffener 220, and the first socket 120 may be fixed onto the stiffener 220 by a bonding device or connection device or fastening device 240. The region (an extension region or portion 1213) extending onto the stiffener 220 of the first socket body 121 may have a form extending from the sidewall 1212 of the first socket body 121 onto the stiffener 220.

The bonding device 240 may penetrate the first socket body 121, the stiffener 220, and the second substrate 210 to bond or connect or fasten them. For example, the bonding device 240 may penetrate the first socket body 121, the stiffener 220, and the second substrate 210 at the region 1213 extending onto the stiffener 220 of the first socket body 121, thereby bonding the first socket body 121, the stiffener 220, and the second substrate 210.

The bonding device 240 may be a screw, a bolt, a nut, etc.

Since the first socket 120 is secured to the first substrate 110 via the stiffener 220 by the bonding device 240, the underfill resin 171 may be omitted.

For other configurations, the same provisions as those described elsewhere in this specification may be applied, unless otherwise specifically contradicted.

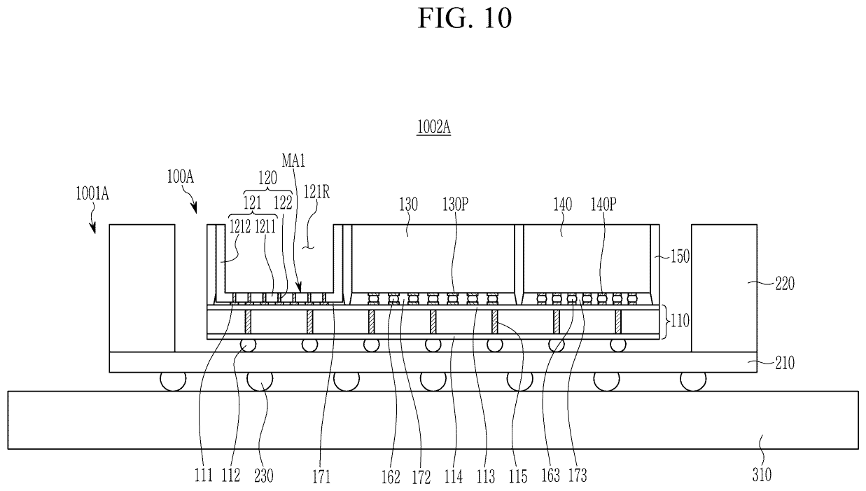

FIG. 10 is a cross-sectional view of a package on board according to some embodiments.

A package on board 1002A according to some embodiments may include a semiconductor package 100A, a second substrate 210 on which the semiconductor package 100A is disposed, and a third substrate 310 on which the second substrate 210 is disposed. For example, the package on board 1002A may be a structure in which the semiconductor package 1001A including the sub-semiconductor package 100A and the second substrate 210 is disposed on the third substrate 310.

The description of the semiconductor package 100A, the second substrate 210, and the configurations of the semiconductor package 100A and the second substrate 210 may be applied equally to the descriptions given in other parts of this specification, unless otherwise specifically contradicted.

The sub-semiconductor package included in the package on board 1002A is not limited to the semiconductor package 100A, and may be the semiconductor packages 1001B, 100C, 100D, and 100E according to other embodiments. Additionally, the 2.5D semiconductor package included in the package on board 1002A is not limited to the semiconductor package 1001A, and may be the semiconductor package 1001B according to other embodiments.

The third substrate 310 may be a printed circuit board. If desired, conductive bumps may be disposed on the lower surface of the third substrate 310.

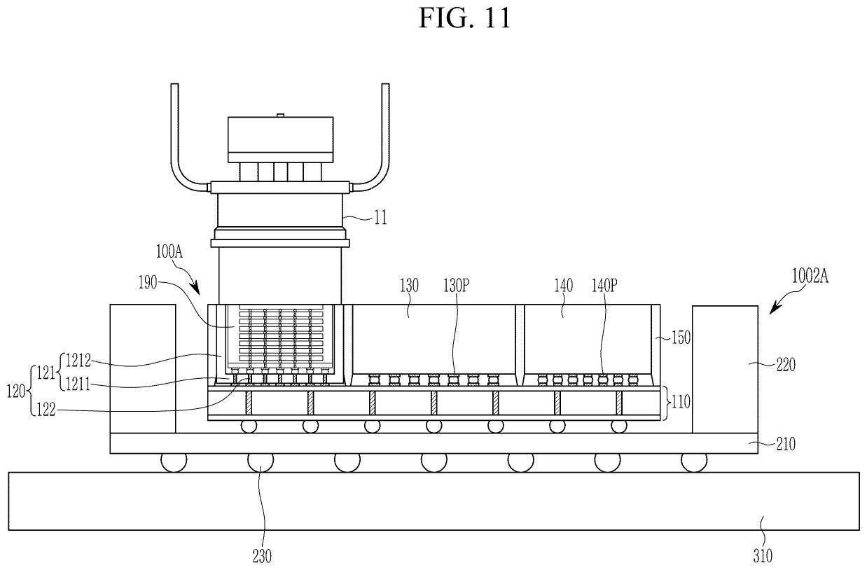

FIG. 11 is a view illustrating an example method for performing an electrical inspection of a semiconductor chip in a package on board illustrated in FIG. 10.

The first semiconductor chip 190 may be transferred and mounted on the mounting region MA1 of the first socket body 121 of the package on board 1002A via a picker 11. The picker 11 may pressurize the first semiconductor chip 190 mounted on the first socket 120, and when being pressurized, the first semiconductor chip 190 may be electrically connected to the first substrate 110 through the first socket pins 122 of the first socket 120. An electrical testing (e.g., an electrical testing for a characteristic verification) of the first semiconductor chip 190 may be performed while being connected to the first substrate 110 by the pressurization of the picker 11.

The first semiconductor chip 190 may be also connected to the third substrate 310, so that an electrical testing may be performed at the board level. If necessary, the first semiconductor chip 190 may be electrically inspected at the package level in the state of the sub-semiconductor package 100A or the 2.5D semiconductor package 1001A that is not connected to the third substrate 310.

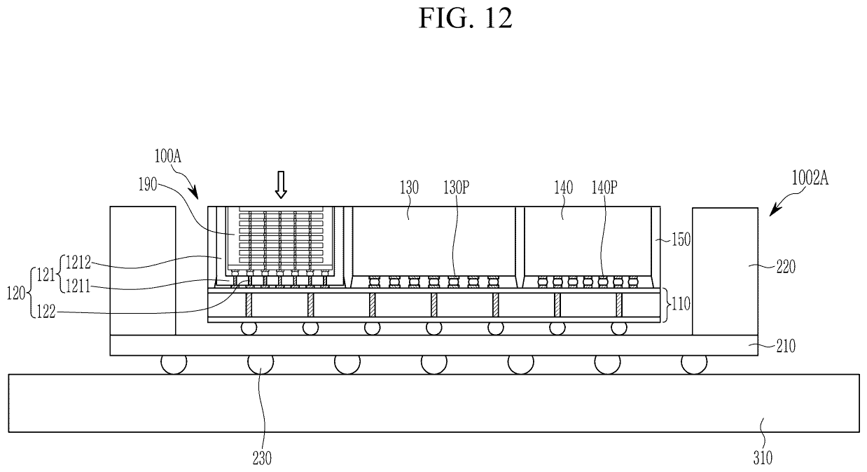

FIG. 12 is a view showing a semiconductor chip accommodated in an accommodating groove of a socket and connected to a socket in a package on board illustrated in FIG. 10.

The first semiconductor chip 190 may be transported and mounted on the mounting region MA1 of the first socket body 121 of the package on board 1002A by using a transport apparatus such as a picker. The first semiconductor chip 190 may be electrically connected to the first substrate 110 through the first socket pins 122 of the first socket 120 by being pressed by another configuration of the product on which the package on board 1002A is mounted. In other words, the first semiconductor chip 190 may be present within a product in a state of being electrically connected to the first substrate 110 by being pressurized by other components of the product.

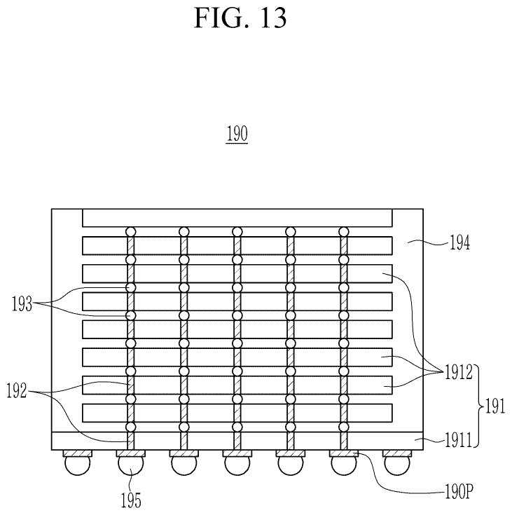

FIG. 13 is an example cross-sectional view of a semiconductor chip connected to a socket.

The first semiconductor chip 190 may be a high bandwidth memory chip.

The first semiconductor chip 190 may include pad(s) 190P disposed on the lower surface. The pads 190P may be connected to the first socket pins 122 of the first socket 120. The material of pad 190P may be a conductive material, for example copper (Cu), aluminum (Al), gold (Au), platinum (Pt), silver (Ag), tin (Sn), chromium (Cr), palladium (Pd), or an alloy of two or more of these.

A conductive bump 195 may be disposed on the lower surface of the pad 190P. The conductive bump 195 may be disposed on the first socket pin 122 and transmit a pressure to the first socket pin 122 when the first semiconductor chip 190 is pressurized. A conductive material such as a solder may be used as the material for conductive bump 195. There are no special restrictions on the number, spacing, or arrangement of the conductive bumps 195.

The first semiconductor chip 190 may be a high bandwidth memory chip and may have a structure in which a plurality of semiconductor chips 191 are stacked, including a buffer chip 1911 and core chips 1912 stacked on the buffer chip 1911. Each semiconductor chip 191 may include through vias 192 for up and down connections. The semiconductor chips 191 may be connected to each other through micro bumps 193, or the pads of the semiconductor chips 191 may be connected to each other by being contact with each other through a metal hybrid bonding (e.g., a Cu—Cu bonding). The stacked semiconductor chips 191 may be encapsulated with an encapsulant 194.

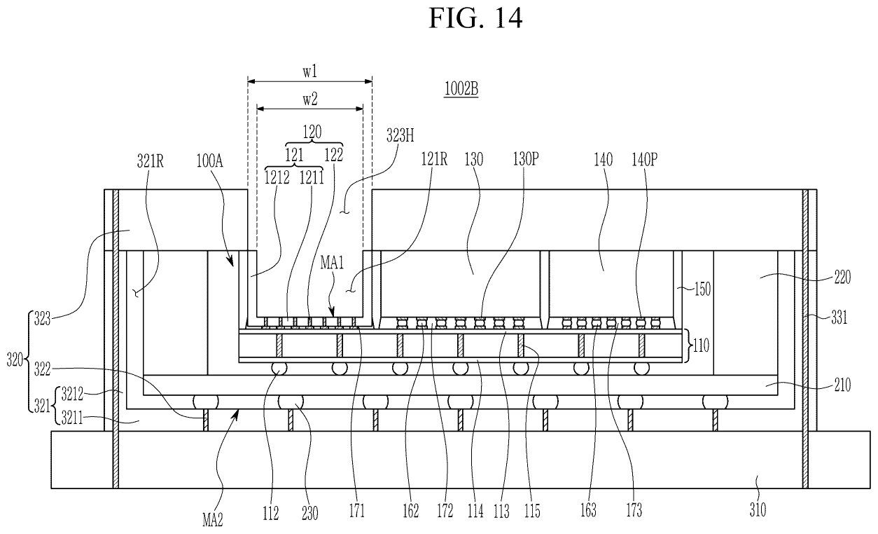

FIG. 14 is a cross-sectional view of a package on board according to some embodiments.

Compared to the package on board 1002A, the package on board 1002B may further include a second socket 320 accommodating the semiconductor package 100A and the second substrate 210 and disposed on the third substrate 310. The semiconductor package 100A and the second substrate 210 may be accommodated in the second socket 320 in the state of the semiconductor package 1001A with the semiconductor package 100A mounted on the second substrate 210.

The second socket 320 may include a second socket body 321 and second socket pins 322.

The material of the second socket body 321 may be an insulating material, but a conductive material may also be used if necessary. When using the conductive material as the material of the second socket body 321, an electrical insulation with the second socket pins 322 may be required.

The second socket body 321 may have a mounting region MA2 on which the second substrate 210 and the semiconductor package 100A are mounted. The second substrate 210 may be connected to or separated from the second socket 320 by a simple mounting and detachment while the semiconductor package 100A is mounted thereon.

The second substrate 210 may be disposed on the mounting region MA2 such that the conductive bump 230 disposed on the lower surface of the second substrate 210 may be in contact with the second socket pin 322.

In some embodiments, the second socket body 321 may include a bottom surface 3211 providing the mounting region MA2 and a sidewall 3212 extending upward from the bottom surface 3211 from the edge of the bottom surface 3211. The mounting region MA2 may be a part or all of the region where the second substrate 210 is mounted among the bottom surface 3211 of the second socket body 321. The bottom surface 3211 and the sidewall 3212 of the second socket body 321 may be connected to each other to provide the accommodating groove 321R for accommodating the semiconductor package 100A and the second substrate 210. The second substrate 210 may be inserted into the accommodating groove 321R with the semiconductor package 100A mounted thereon and be settled on the bottom surface 3211, thereby being easily mounted on the mounting region MA2.

However, the second socket body 321 may include only the bottom surface 3211 and may not include the sidewall 3212 (the similar structure to the first socket body 121 illustrated in FIG. 6). If the second socket body 321 does not include the sidewall 3212, the second substrate 210 mounted with the semiconductor package 100A mounted thereon may be mounted on the mounting region MA2 of the second socket body 321 by a vision recognition.

The second socket pins 322 may pass through the second socket body 321 in the mounting region MA2 and may be electrically connected to the third substrate 310.

The upper and lower ends of the second socket pin 322 may be exposed on the second socket body 321 for the connection with the second substrate 210 and the third substrate 310, respectively. For example, the upper and lower ends of the second socket pin 322 may be protruded onto the second socket body 321 (having the similar structure to the first socket pin 122 illustrated in FIG. 2). The upper end of the second socket pin 322 may have a shape suitable for receiving the conductive bump 230 of the second substrate 210.

For the second socket pin 322, a pogo pin, a probe head, or a silicon rubber pin may be used, but the type of the second socket pin 322 is not limited to these.

The second socket 320 may further include a heat dissipation structure 323 disposed on the second socket body 321 and connected to the second socket body 321.

The heat dissipation structure 323 may extend onto the second substrate 210 and the semiconductor package 100A. The heat dissipation structure 323 may cover at least a portion of each of the second semiconductor chip 130 and the third semiconductor chip 140. For example, the heat dissipation structure 323 may be in contact with and directly cover upper surfaces of the second semiconductor chip 130 and the third semiconductor chip 140, respectively. Since the heat dissipation structure 323 covers the semiconductor chips 130 and 140, the heat generated from them may be efficiently dissipated to the outside of the semiconductor package 100A through the heat dissipation structure 323.

When the stiffener 220 is disposed on the second substrate 210, the heat dissipation structure 323 may cover the stiffener 220. For example, the heat dissipation structure 323 may be in contact with an upper surface of the stiffener 220 and directly cover it. By covering the stiffener 220 with the heat dissipation structure 323, the heat dissipation characteristics of the semiconductor package 100A may be further improved.

The heat dissipation structure 323 may have an opening 323H that vertically overlaps the mounting region MA1 of the first socket body 121. The first semiconductor chip 190 may be mounted on and detached from the mounting region MA1 of the first socket body 121 through the opening 323H of the heat dissipation structure 323. The cross-sectional width w1 of the opening 323H may be greater than or equal to the cross-sectional width w2 of the accommodating groove 121R. For the alignment margin of the first semiconductor chip 190, the cross-sectional width w1 of the opening 323H may preferably be formed to be larger than the cross-sectional width w2 of the accommodating groove 121R.

Conductive materials such as copper (Cu) and aluminum (Al) may be used as the material for the heat dissipation structure 323.

In some embodiments, the second socket 320 may be secured on the third substrate 310 by a bonding device or connection device or fastening device 331.

The bonding device 331 may penetrate the heat dissipation structure 323, the second socket body 321, and the third substrate 310 to bond or connect or fasten the heat dissipation structure 323, the second socket body 321, and the third substrate 310. For example, the bonding device 331 may penetrate the sidewall 3212 of the second socket body 321 to bond the second socket body 321, the heat dissipation structure 323, and the third substrate 310.

The bonding device 331 may be a screw, a bolt, a nut, etc.

For other configurations, the same provisions as those described elsewhere in this specification may be applied, unless otherwise specifically contradicted.

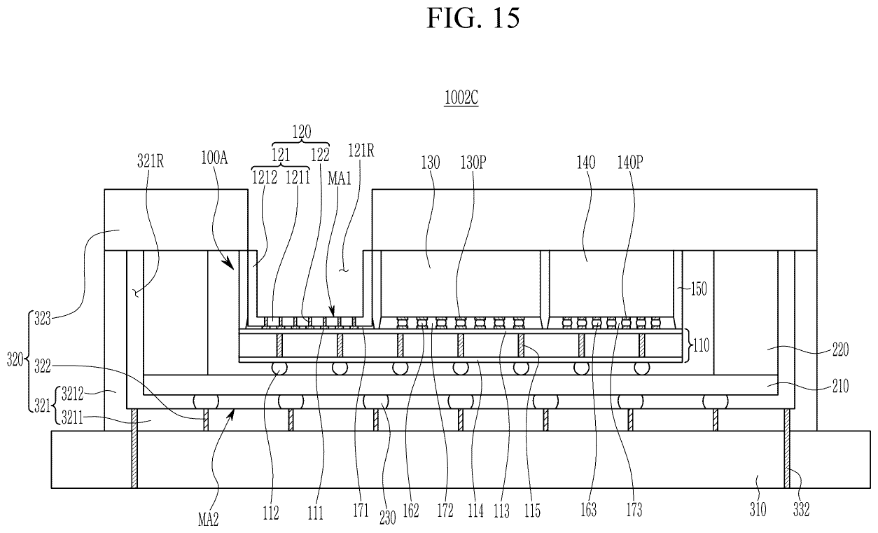

FIG. 15 is a cross-sectional view of a package on board according to some embodiments.

Compared to the case of the package on board 1002B, in the package on board 1002C, the bonding device or connection device or fastening device 332 may penetrate the second socket body 321 and the third substrate 310 to bond or connect or fasten the second socket body 321 and the third substrate 310. For example, the bonding device 332 may penetrate the bottom surface 3211 of the second socket body 321 and the third substrate 310 to bond the second socket body 321 and the third substrate 310.

The bonding device 332 may not penetrate the heat dissipation structure 323, and the heat dissipation structure 323 may be connected to the second socket body 321 as a separate device.

The bonding device 332 may also be a screw, a bolt, a nut, etc.

For other configurations, the same provisions as those described elsewhere in this specification may be applied, unless otherwise specifically contradicted.

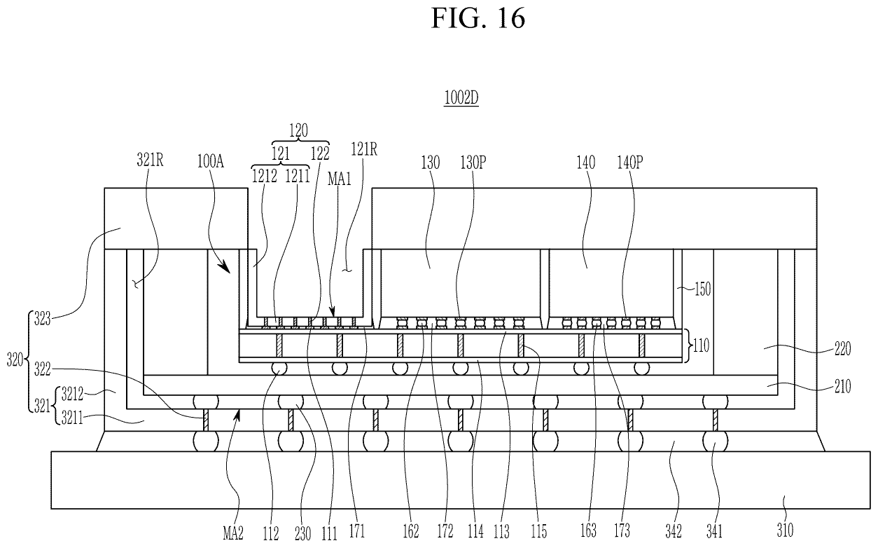

FIG. 16 is a cross-sectional view of the package on board according to another embodiment.

Compared to the package on board 1002B, the second socket 320 in the package on board 1002D may be mounted and fixed on the third substrate 310 by the conductive bump 341. Additionally, the second socket 320 may be connected to the third substrate 310 via a conductive bump 341. The conductive bump 341 may be positioned between the lower end of the second socket pin 322 and the third substrate 310 to connect them. A conductive material such as a solder may be used as the material for conductive bump 341. The conductive bump 341 may be covered with or surrounded by an underfill resin 342 that may fill the space between the second socket 320 and the third substrate 310, but the underfill resin 342 may be omitted.

For other configurations, the same provisions as those described elsewhere in this specification may be applied, unless otherwise specifically contradicted.

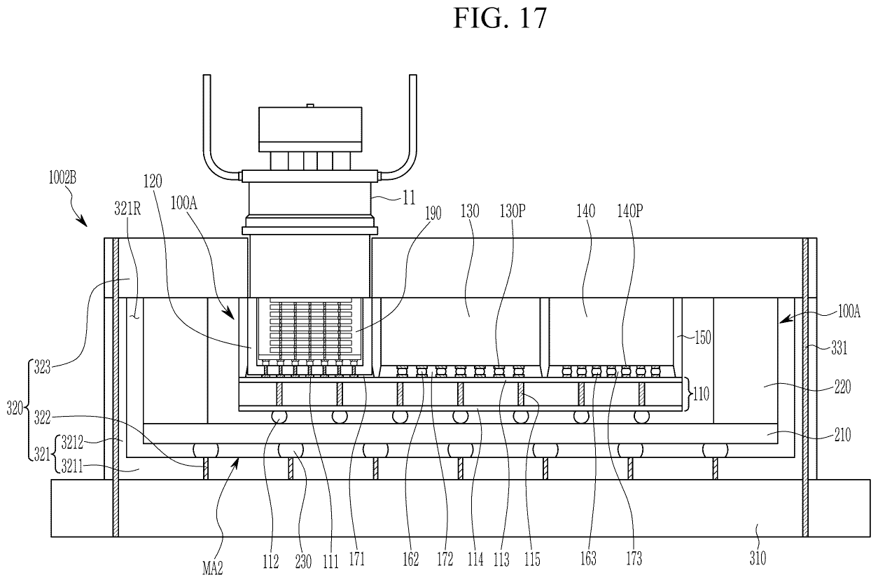

FIG. 17 is a view illustrating an example method for performing an electrical testing on a package on board illustrated in FIG. 14.

The package on board 1002B may be used for the electrical testing of the semiconductor package 1001A. The semiconductor package 1001A may be connected to and disconnected from the third substrate 310 through the second socket 320, and the electrical inspection can be performed at the board level by being connected to the third substrate 310.

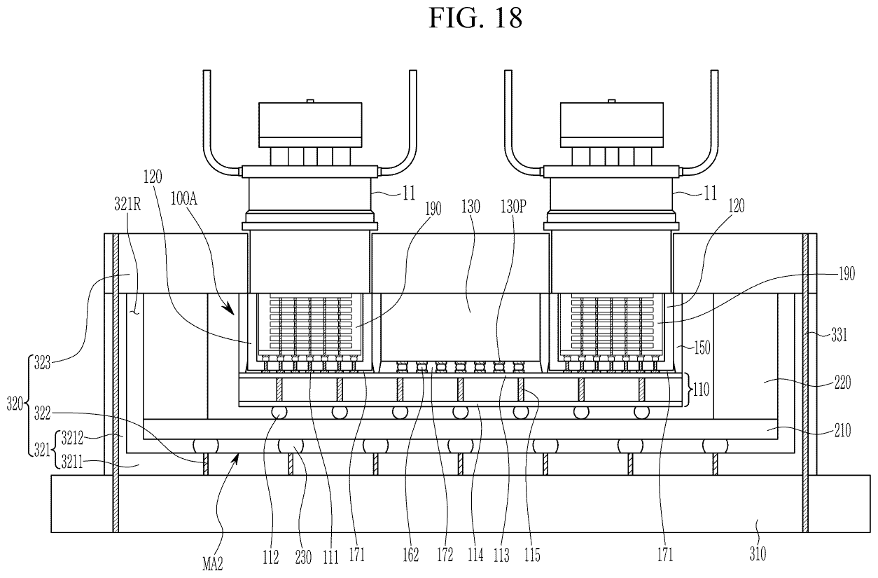

FIG. 18 is a view showing an example method for performing electrical testing on a package on board according to a variation.

If desired, the semiconductor package 100A may also include a plurality of first sockets 120 for mounting a plurality of first semiconductor chips 190. The first semiconductor chip 190 may be transferred and mounted on the mounting region MA1 of each of the first sockets 120 via the picker 11.

By performing the electrical inspection using the same package on board for the plurality of first semiconductor chips 190, an assembly time and cost of the package on board for the electrical inspection may be reduced.

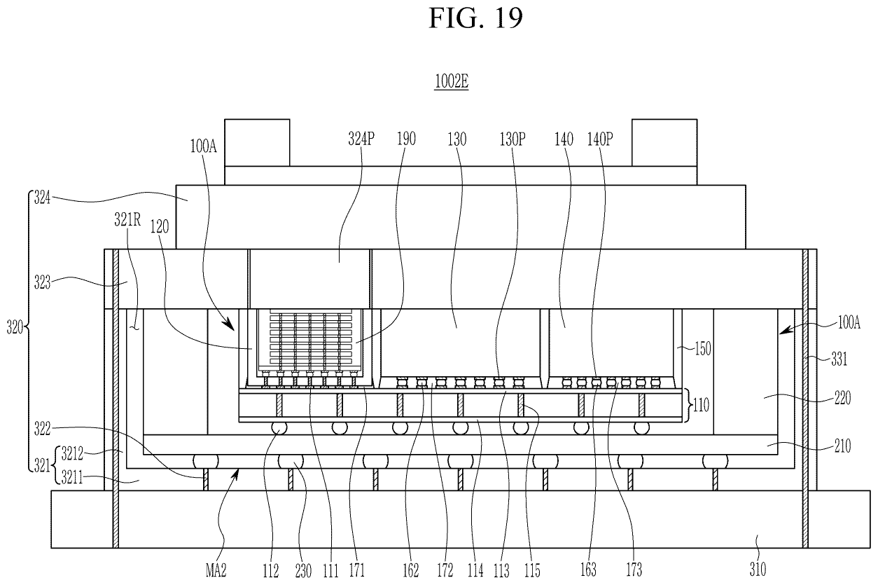

FIG. 19 is a cross-sectional view of a package on board according to some embodiments.

Compared with the case of the package on board 1002B, the semiconductor package 100A in the package on board 1002E may further include a first semiconductor chip 190 mounted in the mounting region MA1 of the first socket body 121. The first semiconductor chip 190 may be transported and mounted on the mounting region MA1 of the first socket body 121 by using a transport apparatus such as a picker.

The first semiconductor chip 190 may be pressurized by the second socket 320 and electrically connected to the first substrate 110 through the first socket pins 122 of the first socket 120.

In some embodiments, the second socket 320 further includes a lid 324 disposed on the second socket body 321 and connected to the second socket body 321, and the first semiconductor chip 190 may be pressed by the lid 324. The lid 324 may be disposed on the heat dissipation structure 323 and may have a protruding portion or plug 324P that protrudes downwardly to be in or fill the opening of the heat dissipation structure 323 and pressurizes the first semiconductor chip 190. The lid 324 may be a manual lid including a handle, but is not limited thereto.

For other configurations, the same provisions as those described elsewhere in this specification may apply, unless otherwise specifically contradicted.

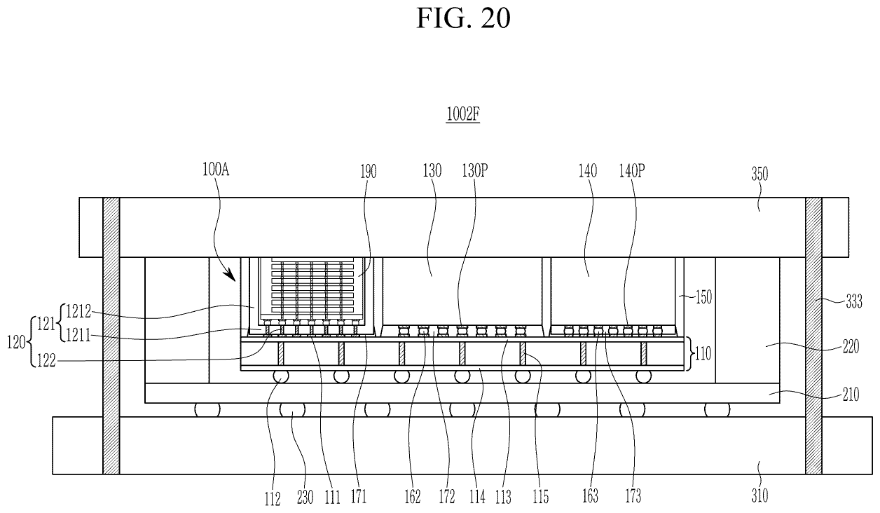

FIG. 20 is a cross-sectional view of a package on board according to some embodiments.

Compared with the case of the package on board 1002A, the semiconductor package 100A in the package on board 1002F may further include a first semiconductor chip 190 mounted in the mounting region MA1 of the first socket body 121.

Additionally, the package on board 1002F may further include a heat dissipation structure 350 that is disposed extending over the third substrate 310 and the semiconductor package 100A and pressurizes the first semiconductor chip 190.

The heat dissipation structure 350 may be extended onto the second substrate 210 and the semiconductor package 100A. The heat dissipation structure 350 may cover at least a portion of each of the first semiconductor chip 190, the second semiconductor chip 130, and the third semiconductor chip 140. For example, the heat dissipation structure 350 may be in contact with and directly cover upper surfaces of the first semiconductor chip 190, the second semiconductor chip 130, and the third semiconductor chip 140, respectively. As the heat dissipation structure 350 covers the semiconductor chips 130, 140, and 190, the heat generated from them may be efficiently dissipated to the outside of the semiconductor package 100A through the heat dissipation structure 350.

When the stiffener 220 is disposed on the second substrate 210, the heat dissipation structure 350 may cover the stiffener 220. For example, the heat dissipation structure 350 may be in contact with an upper surface of the stiffener 220 and directly cover it. By covering the stiffener 220 with the heat dissipation structure 350, the heat dissipation characteristics of the semiconductor package 100A may be further improved.

Conductive materials such as copper (Cu) and aluminum (AI) may be used as materials for the heat dissipation structure 350.

The heat dissipation structure 350 may be fixed on the third substrate 310 by a bonding device or connection device or fastening device 333.

The bonding device 333 may penetrate the heat dissipation structure 350 and the third substrate 310 to bond or connect or fasten the heat dissipation structure 350 and the third substrate 310. The bonding device 333 may penetrate the heat dissipation structure 350 and the third substrate 310 at the edge region of the heat dissipation structure 350 and the third substrate 310, for example, spaced apart from the outer region of the second substrate 210 to bond the heat dissipation structure 350 and the third substrate 310.

Additionally, the bonding device 333 may adjust the gap between the heat dissipation structure 350 and the third substrate 310 so that the heat dissipation structure 350 pressurizes the first semiconductor chip 190.

The bonding device 333 may be a screw, bolt, nut, etc.

For other configurations, the same provisions as those described elsewhere in this specification may be applied, unless otherwise specifically contradicted.

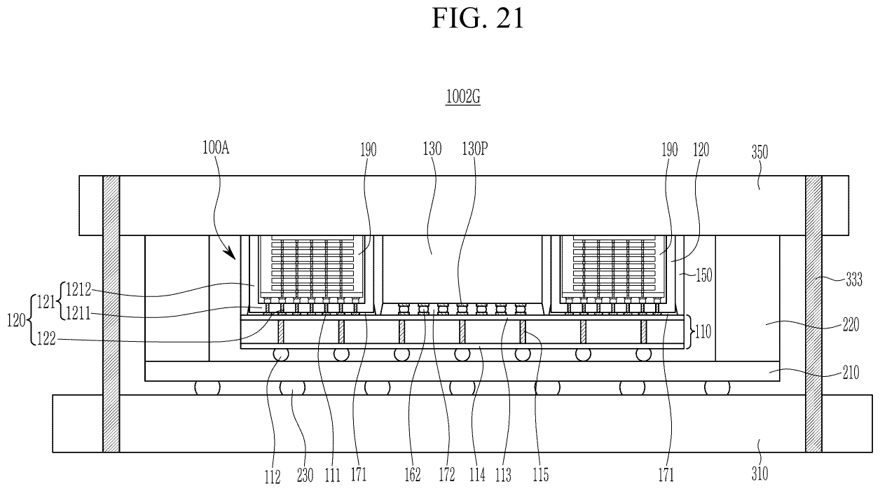

FIG. 21 is a cross-sectional view of a package on board according to some embodiments.

Compared to the case of the package on board 1002F, the semiconductor package 100A in the package on board 1002G may include a plurality of first sockets 120 and first semiconductor chips 190 mounted on each of them. The heat dissipation structure 350 may simultaneously pressurize the first semiconductor chips 190.

For other configurations, the same provisions as those described elsewhere in this specification may apply, unless otherwise specifically contradicted.

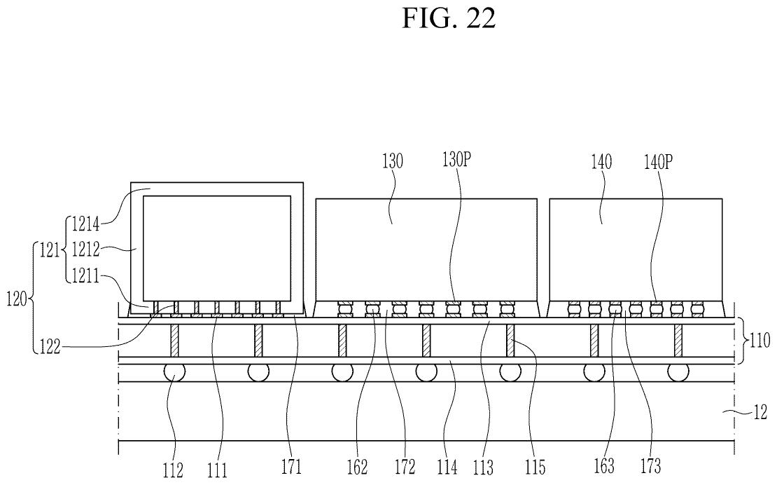

FIG. 22 to FIG. 24 are views illustrating an example manufacturing method for a semiconductor package illustrated in FIG. 1.

First, referring to FIG. 22, a first substrate 110 is disposed on a carrier substrate 12, and a first socket 120 and semiconductor chips 130 and 140 before a processing are disposed on the first substrate 110.

The first substrate 110 may be a wafer level substrate, but the drawing shows only a portion of the first substrate 110 at the wafer level.

The first socket body 121 of the first socket 120 before a processing may include a bottom surface or bottom wall 1211, an upper surface or upper wall 1214, and a sidewall 1212 connecting the bottom surface 1211 and the upper surface 1214, and the bottom surface 1211, the upper surface 1214, and the sidewall 1212 may provide a blank space surrounded by them.

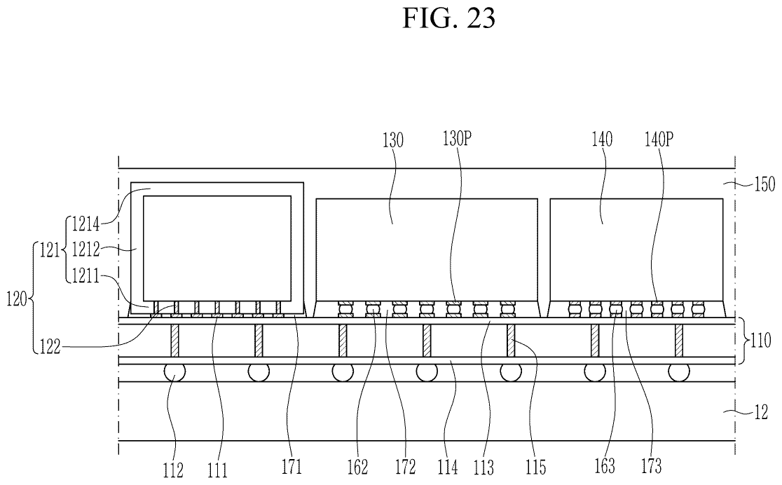

Next, referring to FIG. 23, the first socket 120 and the semiconductor chips 130 and 140 are sealed with an encapsulant 150 before the processing. The encapsulating may be accomplished by a compression molding, a transfer molding, etc.

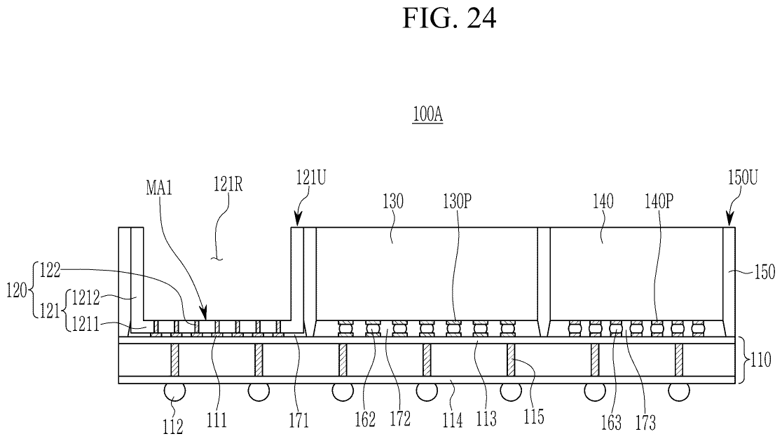

Finally, referring to FIG. 24, the upper surface of the encapsulant 150 is grinded, and the upper surface 1214 of the first socket 120 before the processing is removed to form the first socket 120 having an accommodating groove 121R. At this time, the upper surfaces of the semiconductor chips 130 and 140 may be grinded together. Additionally, the first substrate 110 and the encapsulant 150 at the wafer level may be sawed to be separated into individual semiconductor packages to manufacture a semiconductor package 100A.

While this disclosure has been described in connection with what is presently considered to be practical example embodiments, it is to be understood that the disclosure is not limited to the disclosed embodiments, but, on the contrary, is intended to cover various modifications and equivalent arrangements included within the spirit and scope of the appended claims.

Additionally, the example embodiments of the present disclosure are not independent of each other and may be implemented in combination with each other unless specifically contradictory. Therefore, the combined embodiment of the present disclosure should also be considered as included in the scope of the present disclosure.

What is claimed is:

1. A semiconductor package comprising:
a substrate;
a socket on the substrate and including a socket body having a mounting region on which a first semiconductor chip is mounted and socket pins penetrating the socket body and electrically connected to the substrate; and
one or more second semiconductor chips disposed side by side on the substrate adjacent the socket.

2. The semiconductor package of claim 1, wherein:
the socket body includes a bottom surface providing the mounting region and a sidewall extending upwardly from an edge of the bottom surface, and
the mounting region and the sidewall are connected to each other to define an accommodating groove in which the first semiconductor chip is accommodated.

3. The semiconductor package of claim 1, further comprising:
an underfill resin that fills at least a portion of a space between the socket body and the substrate and connects the socket body and the substrate.

4. The semiconductor package of claim 1, further comprising:
a bonding device that bonds the socket body and the substrate by penetrating the socket body and the substrate.

5. The semiconductor package of claim 1, further comprising:
an encapsulant on the substrate that seals the socket and the one or more second semiconductor chips.

6. The semiconductor package of claim 5, wherein:
an upper surface of the socket body and an upper surface of the encapsulant are substantially coplanar.

7. The semiconductor package of claim 1, wherein:
each second semiconductor chip includes a logic chip or a high bandwidth memory chip.

8. A semiconductor package comprising:
a first substrate; and
a sub-semiconductor package on the first substrate,
wherein the sub-semiconductor package includes:
a second substrate;
a socket on the second substrate and including a socket body having a mounting region on which a first semiconductor chip is mounted, and socket pins penetrating the socket body and electrically connected to the second substrate; and
a second semiconductor chip on the second substrate adjacent the socket.

9. The semiconductor package of claim 8, further comprising:
a stiffener spaced apart from the sub-semiconductor package on the first substrate.

10. The semiconductor package of claim 9, wherein:
the socket body extends over the stiffener, and
the semiconductor package further comprises a connection device that penetrates the socket body, the stiffener and the first substrate to connect the socket body, the stiffener and the first substrate.

11. A package on board comprising:
a first substrate;
a second substrate on the first substrate; and
a semiconductor package on the second substrate,
wherein the semiconductor package includes:
a third substrate;
a first socket on the third substrate and including a first socket body having a mounting region on which a first semiconductor chip is mounted, and first socket pins penetrating the first socket body and electrically connected to the third substrate; and
a second semiconductor chip on the third substrate adjacent the first socket.

12. The package on board of claim 11, further comprising:
a second socket on the first substrate and including a second socket body having an accommodating groove and second socket pins penetrating the second socket body and electrically connected to the first substrate, and
wherein the second substrate and the semiconductor package are positioned within the accommodating groove of the second socket body.

13. The package on board of claim 12, wherein:
a fastening device that fastens the second socket body and the first substrate by penetrating the second socket body and the first substrate.

14. The package on board of claim 12, wherein:
the second socket further includes a heat dissipation structure on the second socket body, extending on the second substrate and the semiconductor package, and having an opening vertically overlapping the mounting region of the first socket body.

15. The package on board of claim 14, wherein:
the heat dissipation structure covers the second semiconductor chip.

16. The package on board of claim 14, further comprising:
a stiffener spaced apart from the semiconductor package on the second substrate, and
wherein the heat dissipation structure covers the stiffener.

17. The package on board of claim 14, further comprising:
a bonding device that penetrates the heat dissipation structure, the second socket body, and the first substrate to connect the heat dissipation structure, the second socket body, and the first substrate.

18. The package on board of claim 12, wherein:
the semiconductor package further includes a first semiconductor chip mounted on the mounting region of the first socket body, and
the second socket further includes a lid on the second socket body and configured to pressurize the first semiconductor chip.

19. The package on board of claim 11, wherein:
the semiconductor package further includes a first semiconductor chip mounted on the mounting region of the first socket body, and
the package on board further comprises a heat dissipation structure extending over the second substrate and the semiconductor package and configured to pressurize the first semiconductor chip.

20. The package on board of claim 19, further comprising:
a bonding device that penetrates the heat dissipation structure and the first substrate to bond the heat dissipation structure and the first substrate.
